(19) United States
(12) Patent Application Publication
(10) Pub. No.: US 2022/0179374 A1
(43) Pub. Date: Jun. 9, 2022

(54) EVALUATION AND/OR ADAPTATION OF INDUSTRIAL AND/OR TECHNICAL PROCESS MODELS

(71) Applicant: Calejo Industrial Intelligence AB, Sundsvall (SE)

(72) Inventor: Leonard KABERG JOHARD, Kazan (RU)

(73) Assignee: Calejo Industrial Intelligence AB, Sundsvall (SE)

(21) Appl. No.: 17/603,746

(22) PCT Filed: Apr. 3, 2020
(86) PCT No.: PCT/SE2020/050351

§ 371 Date: Oct. 14, 2021

(30) Foreign Application Priority Data
Apr. 18, 2019 (SE) 1950490-1

(51) Int. Cl. G05B 13/04; G05B 13/02

(52) U.S. Cl. CPC G05B 13/042; G05B 13/027

(57) ABSTRACT

There is provided a method and corresponding systems and computer-programs for evaluating and/or adapting one or more technical models related to an industrial and/or technical process. The method comprises obtaining a fully or partially acausal modular parameterized model of an industrial and/or technical process comprising at least one physical sub-model and at least one neural network sub-model, including one or more parameters of the parameterized model. The method further comprises generating a system of differential equations based on the parameterized model, and simulating the dynamics of one or more states of the industrial and/or technical process over time based on the system of differential equations. The method also comprises applying reverse-mode automatic differentiation with respect to the system of differential equations when simulating the industrial and/or technical process in order to generate an estimate representing an evaluation of the model of the industrial and/or technical process.

### TECHNICAL FIELD

The invention generally relates to industrial and/or technical processes and process control and more specifically concerns the technical field of industrial/technical modelling and/or model/control parameter optimization.

### BACKGROUND

Industrial and/or technical process control normally involves collecting technical data from sensors coupled to an industrial and/or technical system, refining this technical data into some technical knowledge (modeling) and using the knowledge to produce control signals that create an efficient operation of the industrial and/or technical process.

For these purposes most industries employ some kind of modelling software that assist them in creating knowledge models that can interact with their data. These models are generally encoded in an industry-specific object-oriented modelling language. In some cases the models are based on physical equations derived from theory, in other cases the models are based on statistical methods such as regression analysis, and in yet other cases the model is based on so-called genetic optimization algorithms that may be used for solving both constrained and unconstrained optimization problems based on a natural selection process that mimics biological evolution.

To increase the reuse of knowledge in such models there has been a tendency to employ acausal declarative modelling languages, such as Modelica or Modia, where the simulation details and processing orders are clearly separated from the physical models. Due to the increased complexity of such modelling systems these acausal declarative modelling languages are typically implemented as general-purpose frameworks or software that can then be adapted to various industries through solver-settings and/or model libraries. These new modelling languages are able to scale modelling efforts through much more efficient reuse of human labour in the modelling process.

At the same time there is a need to model systems using Artificial Intelligence (AI) methods such as neural networks and other similar universal function approximators in order to reduce the need for expensive manual modelling hours and/or for modelling systems with unknown behaviour. These systems are generally causally defined black boxes written in special software that is able to exploit computationally efficient algorithms such as backpropagation. A disadvantage with such black box methods is they tend to have little possibility of reuse due to a lack of modularity, difficulty of interpretation and enforced causality at all steps. Additionally, the standard standalone gradient descent approach of individual universal function approximator training becomes inefficient when they are integrated in other systems being optimized at the same time, as the modification of other parts may move the optima for each component.

The industrial tendency to digitalize the operations and the possibility to create more complex models with the improved modelling languages means that modelling systems are facing new magnitudes of data that cannot be solved with current computational systems and methods.

### SUMMARY

It is a general object to provide efficient evaluation and/or adaptation of technical model(s) of industrial and/or technical processes, and/or improved control of industrial and/or technical processes.

In particular, it may be desirable to provide more accurate and efficient computer-aided methods for application to industrial process models and to use these to create improved control of industrial processes.

It is a specific object to provide computationally more efficient calculation of sensor-based error gradients on acausal declarative models that contain universal function approximators.

It is another object to make efficient automized collection, reuse and manipulation of knowledge implicitly encoded in universal function approximators for use in analyzing and/or controlling industrial processes.

It is another object to adapt and/or optimize modelling systems that allow an efficient interaction between human understanding of processes and universal function approximation models.

It is yet another object to provide computationally efficient use of sensor data to provide optimal parameterized control systems and/or policies through human-interpretable semi-supervised reinforcement learning.

It is yet another object to provide data-efficient and computationally efficient reinforcement learning-based optimization of control of industrial and/or technical processes through the use of semi-supervised learning.

It is yet another object to provide efficient control of industrial and/or technical processes.

These and other objects are met by embodiments as defined herein.

In a way, it is desirable to provide a system that interprets acausal declarative models with universal function approximators and provides data in one or two stages in order to create gradients, accurate model parameters, parameterized control, an optimized industrial process and/or models of industrial processes in a computationally efficient manner.

It may also be desirable to provide a method for creating gradients, accurate model parameters, parameterized control, control signals and/or an optimized industrial process using provided parameterized models in an acausal declarative modelling language.

According to a first aspect, there is provided a system comprising:
one or more processors;
a memory configured to store: a fully or partially acausal modular parameterized model of an industrial and/or technical process comprising at least one physical sub-model and at least one neural network sub-model used as a universal function approximator for at least partly modeling the industrial and/or technical process, including one or more model parameters of the fully or partially acausal modular parameterized model;
a simulator configured to, by one or more processors, simulate the industrial and/or technical process based on the fully or partially acausal modular parameterized (process) model and a corresponding system of differential equations, and
an evaluator configured to, by the one or more processors, apply reverse-mode automatic differentiation with respect to the system of differential equations when simulating the industrial and/or technical process in order to generate an evaluation estimate representing an evaluation of the model of the industrial and/or technical process; and
an adaptation module configured to, by the one or more processors (110), receive the evaluation estimate to update at least one model parameter of the fully or partially acausal modular parameterized model of the industrial and/or technical process based on a gradient-descent or ascent procedure.

For example, the evaluator may be configured to generate the evaluation estimate at least partly based on technical sensor data such as one or more time series parameters originating from one or more data collection systems that has monitored the industrial and/or technical process.

By way of example, the system may further comprise, as part of the simulator:
a compiler configured to, by the one or more processors, receive the parameterized process model and create the system of differential equations; and
one or more differential equation solvers configured to, by the one or more processors, receive the system of differential equations and simulate the industrial and/or technical process through time.

In such examples, the memory may also be configured to store: a fully or partially acausal modular parameterized control model for modelling a control process performed by a control system controlling at least part of the industrial and/or technical process, including one or more parameters of the parameterized control model. The fully or partially acausal modular parameterized control model may then be defined for interaction with at least part of the fully or partially acausal modular parameterized model of the industrial and/or technical process as optimized by the updated model parameters. The control process is at least partly modeled by one or more neural networks used as universal function approximator(s). The system may further comprise:
a control simulator configured to, by one or more processors, simulate the control process based on the fully or partially acausal modular parameterized control model and a corresponding system of differential equations, and
a control objective module configured to, by the one or more processors, evaluate a control objective, defined as a control objective function of the states of the control model, of the control system for controlling the industrial and/or technical process;
a control reverse-mode automatic differentiation estimator configured to, by the one or more processors, estimate a gradient of the control objective on the control simulation with respect to one or more control parameters using reverse-mode automatic differentiation with respect to the set of differential equations simulating the control process; and
a control optimizer configured to, by the one or more processors, receive the gradient from the control reverse-mode automatic differentiation estimator and one or more control parameters, and update the control parameters based on gradient-descent or ascent and store the improved control parameters to the memory.

According to a second aspect, there is provided a system configured to evaluate and/or adapt one or more technical models related to an industrial and/or technical process. The system is configured to obtain a fully or partially acausal modular parameterized (process) model of the industrial and/or technical process, including one or more model parameters of the fully or partially acausal modular parameterized model, wherein the fully or partially acausal modular parameterized process model is defined such that the industrial and/or technical process is at least partly modeled by one or more neural networks used as universal function approximator(s). The system is also configured to simulate the industrial and/or technical process based on the fully or partially acausal modular parameterized (process) model and a corresponding system of differential equations. Further, the system is configured to apply reverse-mode automatic differentiation with respect to the system of differential equations and generate an estimate representing an evaluation of the process model of the industrial and/or technical process. The system is also configured to update at least one model parameter of the fully or partially acausal modular parameterized model of the industrial and/or technical process based on the generated evaluation estimate and based on a gradient-descent or ascent procedure, and store the new parameters to memory.

By way of example, the system may be configured to obtain technical sensor data representing one or more states of the industrial and/or technical process at one or more time instances, and the system may be configured to generate the evaluation estimate at least partly based on the technical sensor data. Further, the system may be configured to simulate the dynamics of the state(s) of the industrial and/or technical process over time, and the system may be configured to generate an estimate of a gradient related to one or more simulated states with respect to at least one loss function representing an error between i) the model-based simulated industrial and/or technical process and ii) a real-world representation of the industrial and/or technical process at least partly based on the technical sensor data.

For such cases, when the model parameters have been updated, the system may also be configured to obtain a fully or partially acausal modular parameterized control model of a control process performed by a control system controlling at least part of the industrial and/or technical process, including one or more parameters of the fully or partially acausal modular parameterized control model. The fully or partially acausal modular parameterized control model may then be defined for interaction with at least part of the parameterized model of the industrial and/or technical process as optimized by the updated model parameters. The control process is at least partly modeled by one or more neural networks used as universal function approximator(s). The system is therefore configured to simulate the control process performed by the control system based on the fully or partially acausal modular parameterized control model and a corresponding system of differential equations, apply reverse-mode automatic differentiation with respect to the system of differential equations to generate a control model evaluation estimate, and update at least one parameter of the fully or partially acausal modular parameterized control model based on the control model evaluation estimate.

By way of example, the system may be configured to transfer at least part of the parameters of the control model to the control system for use as a basis for controlling the industrial and/or technical process.

According to a third aspect, there is provided a control system for a technical and/or industrial system, wherein the control system includes and/or interacts with a system according to the second aspect or its sub-aspects.

According to a fourth aspect, there is provided an industrial and/or technical system comprising a system according to the second aspect or its sub-aspects and/or a control system according to the third aspect.

According to a fifth aspect, there is provided a method, performed by one or more processors, for evaluating and/or adapting one or more technical models related to an industrial and/or technical process. Basically, the method comprises:
obtaining a fully or partially acausal modular parameterized model of an industrial and/or technical process comprising at least one physical sub-model and at least one neural network sub-model used as a universal function approximator for at least partly modeling the industrial and/or technical process, including one or more parameters of the fully or partially acausal modular parameterized model;
generating a system of differential equations based on the fully or partially acausal modular parameterized model;
simulating the dynamics of one or more states of the industrial and/or technical process over time based on the system of differential equations; and
applying reverse-mode automatic differentiation with respect to the system of differential equations when simulating the industrial and/or technical process in order to generate an estimate representing an evaluation of the model of the industrial and/or technical process; and
updating at least one model parameter of the fully or partially acausal modular parameterized model of the industrial and/or technical process based on the evaluation estimate using a gradient-descent or ascent procedure.

Preferably, the estimate may be generated at least partly based on technical sensor data originating from the industrial and/or technical process.

By way of example, the step of applying reverse-mode automatic differentiation in order to generate an estimate comprises the step of generating a gradient estimate on a loss function that is based on the simulated states using reverse-mode automatic differentiation.

Optionally, the method may further comprise:
receiving: a fully or partially acausal modular parameterized control model based on at least part of the model of the industrial and/or technical process optimized by the updated model parameter(s) and a parameterized control system for the industrial and/or technical process; a control objective function of the states of the control model encoding an objective of a control of the industrial and/or technical process; and parameters of the control model;
generating states of the control model using one or more differential equation solvers;
generating a gradient estimate on the control objective function with respect to the parameters of the control model using reverse-mode automatic differentiation;
updating one or more of the (control model) parameters of the control model using gradient-descent or ascent on the gradient estimate.

By way of example, the updated parameters of the control model, also referred to as control model parameters, may then be stored in memory or the parameterized control system may be configured according to the updated parameters of the control model.

For example, the updated control model parameters may thereby be applied to control the industrial and/or technical process.

According to a sixth aspect, there is provided a computer program comprising instructions, which when executed by at least one processor, cause the at least one processor to:

obtain a fully or partially acausal modular parameterized process model of an industrial and/or technical process, and the fully or partially acausal modular parameterized (process) model is defined such that the industrial and/or technical process is at least partly modeled by one or more neural networks used as universal function approximator(s);

simulate the industrial and/or technical process based on the fully or partially acausal modular parameterized process model and a corresponding system of differential equations;
apply reverse-mode automatic differentiation with respect to the system of differential equations to generate an estimate representing an evaluation of the model of the industrial and/or technical process; and
update at least one parameter of the parameterized process model of the industrial and/or technical process based on the generated evaluation estimate using a gradient-descent or ascent procedure.

According to a seventh aspect, there is provided a computer program comprising instructions, which when executed by at least one processor, cause the at least one processor to:
obtain a fully or partially acausal modular parameterized control model of a control process performed by a control system controlling at least part of an industrial and/or technical process, including one or more parameters of the fully or partially acausal modular parameterized control model, wherein the control model is at least partly modeled by one or more neural networks used as universal function approximator(s);
simulate the control process performed by the control system based on the fully or partially acausal modular parameterized control model and a corresponding system of differential equations;
apply reverse-mode automatic differentiation with respect to the system of differential equations to generate a control model evaluation estimate; and
update at least one parameter of the parameterized control model based on the control model evaluation estimate using a gradient-descent or ascent procedure.

According to an eighth aspect, there is provided a computer-program product comprising a non-transitory computer-readable medium having stored thereon a computer program according to the sixth or seventh aspect.

In this way, it is possible to provide efficient evaluation and/or adaptation of technical model(s) of industrial and/or technical processes.

By proper evaluation of process models, it is possible to adapt the models and when combined with relevant control models, parameterized control systems may also be evaluated and optimized.

It is also possible to provide more efficient computational procedures for application to industrial and/or technical process models and use these to create improved control of industrial and/or technical processes.

It may also be possible to provide efficient automatic modelling of components of the industrial and/or technical processes in an overall physical model through the standard initialization and later adaptation of universal function approximators. Such optimization of the joint model becomes more efficient by a unified adaptation that avoids interference between separated adaptation processes being adapted individually.

Additionally, it may be possible to perform more efficient semi-supervised reinforcement learning and achieve high data-efficiency through data-reuse from model flexibility, reduced need for data labeling through unsupervised process learning as well as higher computational efficiency than exploratory reinforcement learning methods through reuse of the model logic with automatic differentiation.

The invention is generally applicable to any kind of industrial and technical processes, examples of which will be described in the detailed description.

Other advantages offered by the invention will be appreciated when reading the below description of embodiments of the invention.

### BRIEF DESCRIPTION OF THE DRAWINGS

The invention, together with further objects and advantages thereof, may best be understood by making reference to the following description taken together with the accompanying drawings, in which:

FIG. 1 is a schematic diagram illustrating an example of an industrial and/or technical system and a corresponding model according to an illustrative embodiment.

FIG. 2 is a schematic system overview of an example of a system for model evaluation related to an industrial and/or technical process according an embodiment.

FIG. 3 is a schematic system overview of an example of a system for model evaluation and/or adaptation related to an industrial and/or technical process according an embodiment.

FIG. 4 is a schematic system overview of another example of a system for model evaluation and/or adaptation related to an industrial and/or technical process and a corresponding control system according an embodiment, here exemplified with an integrated implementation for the model of the industrial and/or technical process and the corresponding control model.

FIG. 5 is a schematic system overview of yet another example of a system for model evaluation and/or adaptation related to an industrial and/or technical process and a corresponding control system according an embodiment, here exemplified with a parallelized implementation for the model of the industrial and/or technical process and the corresponding control model.

FIG. 6 is a schematic system overview of a particular example of a system for model evaluation related to an industrial and/or technical process according an embodiment.

FIG. 7 is a schematic system overview of a particular example of a system for model evaluation and/or adaptation related to an industrial and/or technical process according an embodiment.

FIG. 8 is a schematic flow diagram illustrating an example of a method for evaluating and/or adapting one or more technical models related to an industrial and/or technical process according to an embodiment.

FIG. 9 is a schematic diagram illustrating another particular example of a processor-memory implemented system for model evaluation and/or adaptation related to an industrial and/or technical process.

FIG. 10 is a schematic diagram illustrating another particular example of a processor-memory implemented system for model evaluation and/or adaptation related to the control model/system of an industrial and/or technical process.

FIG. 11 is a schematic diagram illustrating an example of a computer-implementation according to an embodiment.

### DETAILED DESCRIPTION

Throughout the drawings, the same reference numbers are used for similar or corresponding elements.

For a better understanding of the proposed technology, it may be useful to begin with a brief system overview and introduction to some example embodiments, followed by a more detailed description of particular example implementations as well as explanations of some useful technical terms.

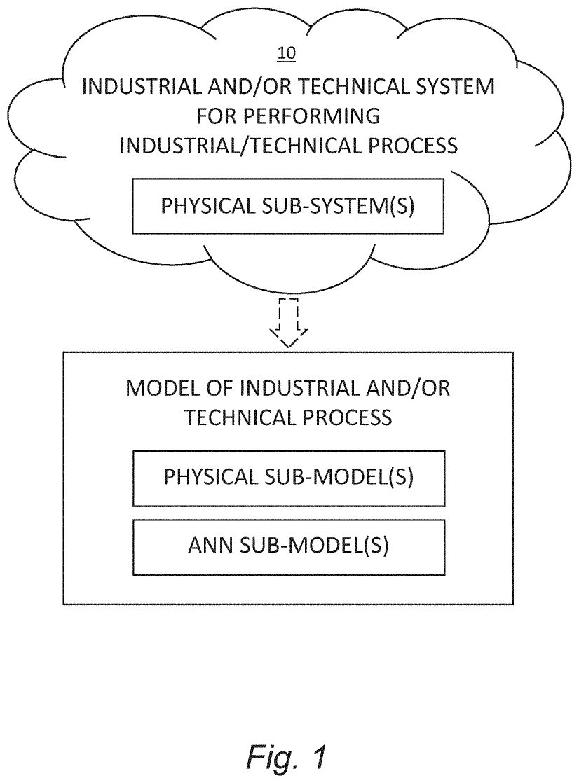

To start with, FIG. 1 is a schematic diagram illustrating an example of an industrial and/or technical system and a corresponding model according to an illustrative embodiment. The physical real-world system such as the industrial and/or technical system 10 may be configured for performing an industrial and/or technical process using one or more physical sub-systems. A corresponding parameterized model, including one or more model parameters, may be built and defined for modelling the industrial and/or technical process defined by the controlled or sometimes uncontrolled operation and behavior of the industrial and/or technical system.

In this particular narrative, the parameterized model of the industrial and/or technical process comprises at least one physical sub-model or sub-system and at least one artificial neural network (ANN) sub-model or sub-system. Preferably, the parameterized model is a fully or partially acausal modular and parameterized model of the industrial and/or technical process, i.e. an acausal modular and parameterized process model. The neural network sub-model may be used as a universal function approximator for at least partly modeling the industrial and/or technical process.

A fully or partially acausal modular parameterized model is a term that applies to acausal modeling of an industrial and/or technical process, which in turn may also or alternatively involve modeling of a control process for controlling an industrial and/or technical process, keeping in mind that such a control process is in itself a technical process.

When modeling an industrial and/or technical process, the model may sometimes be referred to as a process model. When modeling a control process for controlling an industrial and/or technical process, the model may sometimes be referred to as a control model. In some embodiments, both a process model and a control model may exist and interact with each other.

The parameters of the model are generally referred to as model parameters when referring to a general industrial and/or technical process, and control parameters or sometimes control model parameters when referring to a control model for modeling a control process.

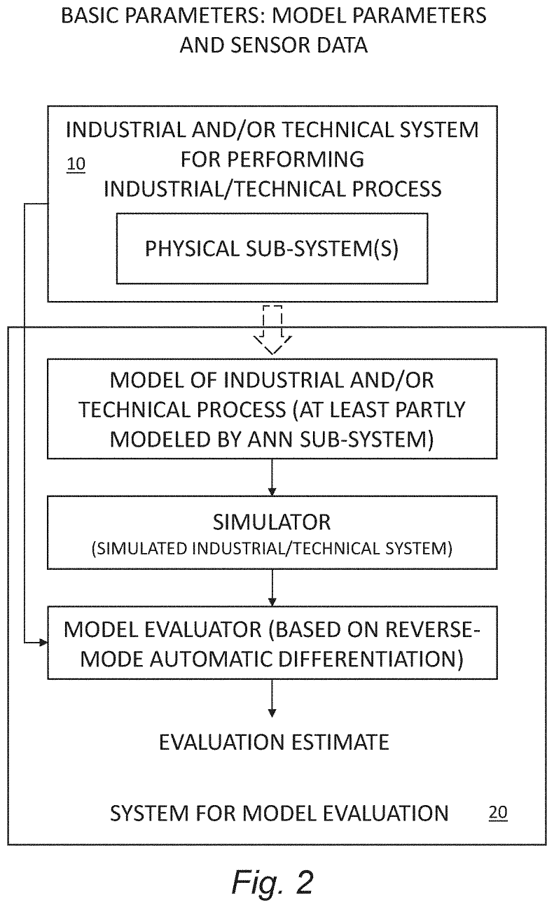

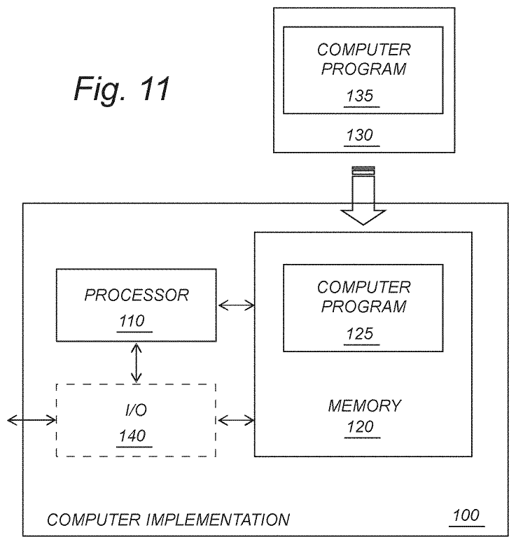

As will be illustrated by way of example with reference to the schematic diagrams of FIG. 2 to FIG. 7 as well as the processor-memory-based implementation of FIG. 11, it can be appreciated that some key features of the proposed technology involves obtaining a parameterized model of the industrial and/or technical process as mentioned above, simulating the industrial and/or technical process based on the parameterized model and a corresponding system of differential equations, and applying reverse-mode automatic differentiation with respect to the system of differential equations and generating an estimate representing an evaluation of the process model of the industrial and/or technical process.

The proposed technology may for example use compiler technology and differential equation solvers for implementation.

The methods and procedures and corresponding systems may be extended to update the model parameters based on the evaluation estimate, and may also incorporate one or more control models for corresponding parameterized control systems and adapt or optimize the control model(s) to generate updated control parameters, thereby improving the control and/or operation of the overall industrial and/or technical process.

FIG. 2 is a schematic system overview of an example of a system for model evaluation related to an industrial and/or technical process according an embodiment. On top, there is a representation of an industrial and/or technical system 10 for performing an industrial and/or technical process, with a corresponding system 20 for model evaluation at the bottom of FIG. 2.

For example, the industrial and/or technical system 10 may be any system within industries such as industrial manufacturing, processing, and packaging, automotive and transportation, mining, pulp, infrastructure, energy and power, telecommunication, information technology, audio/video, life science, oil, gas, water treatment, sanitation and/or aerospace industry.

The industrial and/or technical system 10 includes one or more physical sub-systems such as production lines or sections thereof, industry robots, valves, pumps, generators, electrical grids, vehicles, engines, power station equipment, electronic components, computer-based systems, audio and/or video modules, base stations, routers, servers, cooling and/or heating equipment and so forth.

Based on knowledge about the industrial and/or technical system and its functionality and operating limits, a model of a corresponding industrial and/or technical process may be defined and/or obtained. In our case, the industrial and/or technical process is at least partly modeled by an artificial neural network (ANN) sub-model or sub-system, as mentioned above with reference to FIG. 1. Accordingly, a parameterized model of the industrial and/or technical process comprises at least one physical sub-model and at least one neural network sub-model, as will be explained in more detail later on.

The industrial and/or technical process is then simulated by a simulator based on the generated parameterized model. For example, a compiler and/or interpreter may process information about the model to generate a system of differential equations, and the simulation may then be based on this system of differential equations as processed by one or more differential equation solvers.

Selected outcomes of the simulation of the industrial and/or technical process may then be “compared” to corresponding technical sensor data originating from the industrial and/or technical system 10 in a model evaluator based on reverse-mode auto differentiation to generate an estimate representing an evaluation of the model of the industrial and/or technical process.

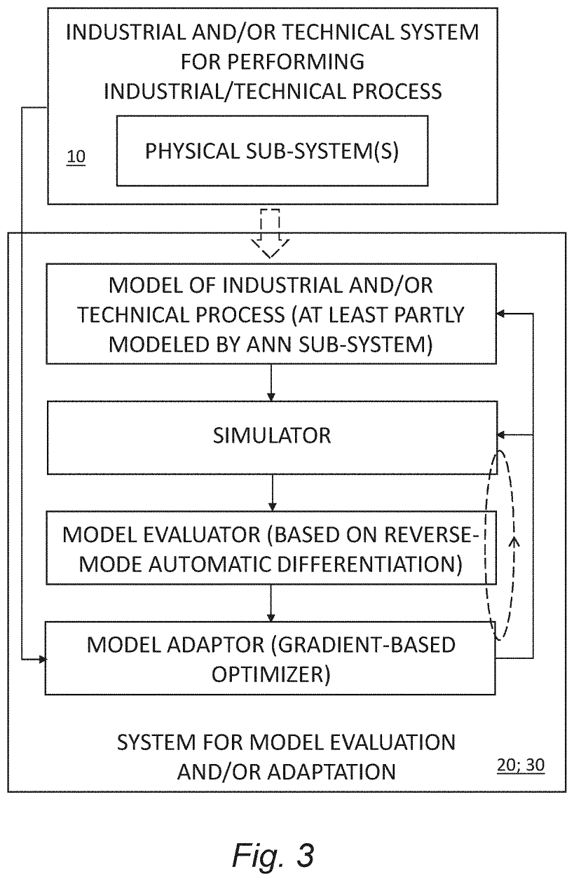

FIG. 3 is a schematic system overview of an example of a system for model evaluation and/or adaptation related to an industrial and/or technical process according an embodiment.

In this particular example, there is provided a system 20; 30 for model evaluation and/or adaptation. In this context, the system further comprises a model adaptor configured to receive the evaluation estimate to update at least one model parameter of the parameterized model of the industrial and/or technical process.

For example, this may optionally be performed in an iterative process (see the dashed circular indication in FIG. 3) with feedback from the model adaptor back to the simulator, until a suitable condition is fulfilled, at which point the model parameter(s) are finally updated.

By way of example, the model adaptor may be implemented as a gradient-based optimizer, as will be exemplified later on.

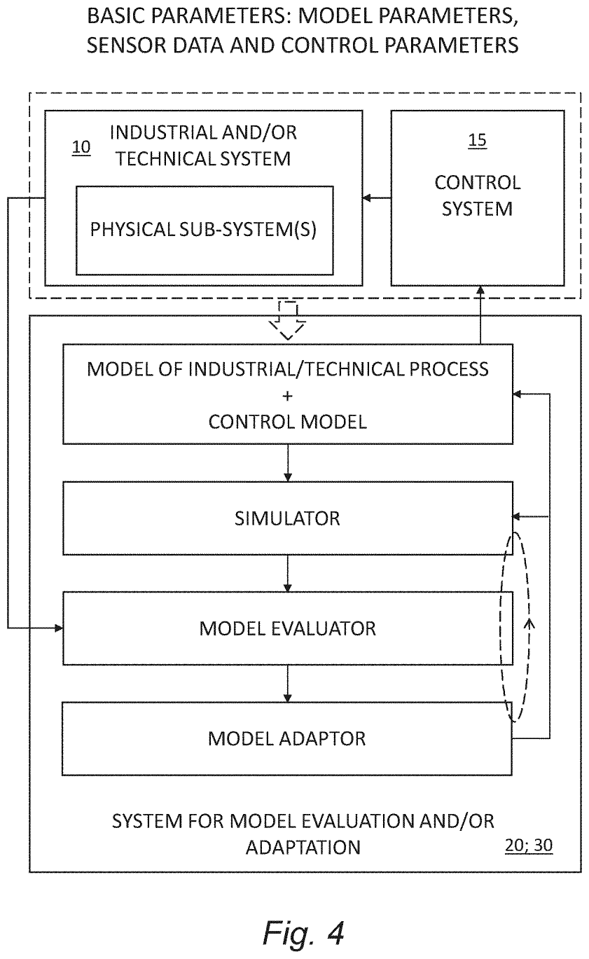

FIG. 4 is a schematic system overview of another example of a system for model evaluation and/or adaptation related to an industrial and/or technical process and a corresponding control system according an embodiment, here exemplified with an integrated implementation for the model of the industrial and/or technical process and the corresponding control model.

The industrial and/or technical system 10 is here connected to a control system 15 configured for controlling at least part of the industrial and/or technical system 10.

In this example, the model of the industrial and/or technical process is combined or integrated with a control model corresponding to a parameterized version of the control system 15. The overall integrated model is then used as a basis for simulating the industrial and/or technical process including the operation of the control system 15 on the industrial and/or technical system 10, and the integrated model is evaluated and adapted, in a similar manner as previously described. In this way, it is possible to evaluate and/or adapt the integrated model, providing the possibility to update one or more parameters of both the parameterized process model and the parameterized control model, thereby allowing improved control of the industrial and/or technical process.

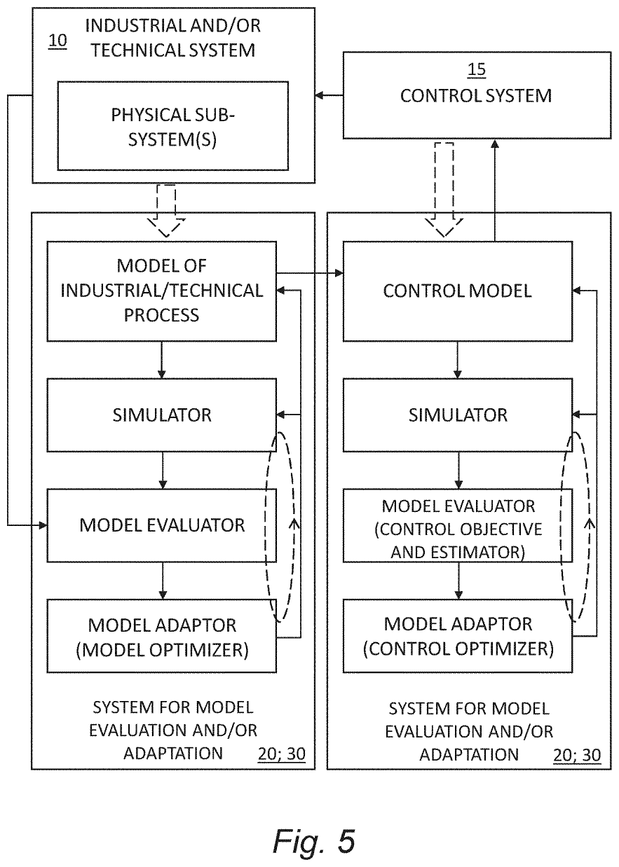

FIG. 5 is a schematic system overview of yet another example of a system for model evaluation and/or adaptation related to an industrial and/or technical process and a corresponding control system according an embodiment, here exemplified with a parallelized implementation for the model of the industrial and/or technical process and the corresponding control model.

In this particular example, a parallel branch is created for evaluating and/or adapting the control model. A first branch for model evaluation and/or adaption is designated for the process model, and a second parallel branch is designated for the control model. Information about the updated process model may be transferred for building and/or adapting the control model. By way of example, the control model evaluator may be operating based on a control objective using a reverse-mode automatic differentiation estimator, and the model adaptor may be a control optimizer using a gradient-based procedure.

The updated control model may ultimately affect the operation of the real-world control system 15, thus influencing the industrial and/or technical system 10 and the process performed by the industrial and/or technical system. In this way, improved process control is achieved.

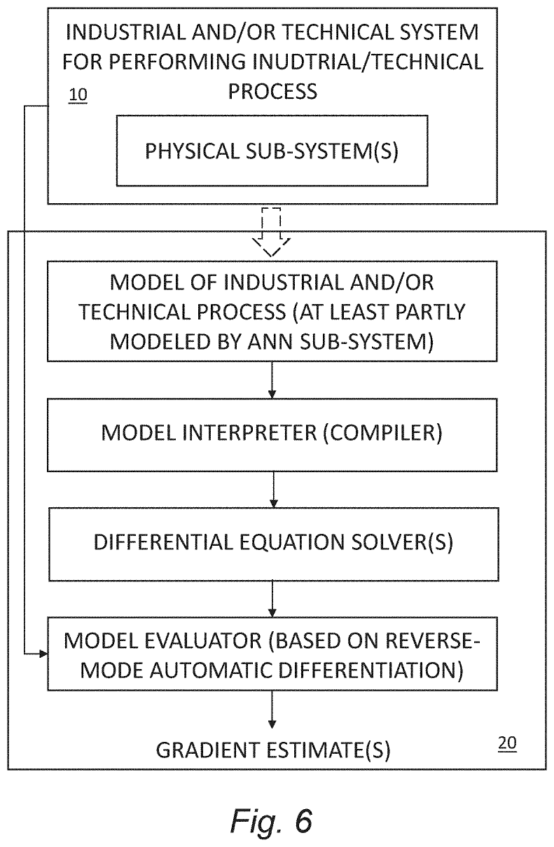

FIG. 6 is a schematic system overview of a particular example of a system for model evaluation related to an industrial and/or technical process according an embodiment. This example corresponds to the more general example of FIG. 2, but here exemplified with a model interpreter such as a compiler for receiving the parameterized model and generating a corresponding system of differential equations, and one or more differential equation solvers for receiving the system of differential equations and simulating the industrial and/or technical process.

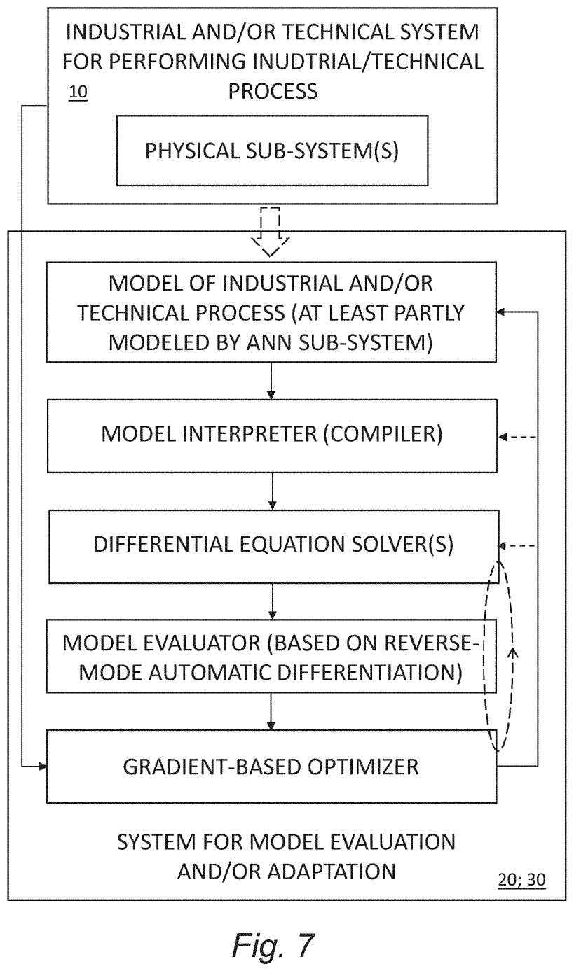

FIG. 7 is a schematic system overview of a particular example of a system for model evaluation and/or adaptation related to an industrial and/or technical process according an embodiment. This example corresponds to the more general example of FIG. 3, but here exemplified with a model interpreter such as a compiler for receiving the parameterized model and generating a corresponding system of differential equations, and one or more differential equation solvers for receiving the system of differential equations and simulating the industrial and/or technical process. Also, the model adaptor is here exemplified by a gradient-based optimizer, which may be operating based on a gradient-descent or ascent procedure.

According to a first aspect, the proposed technology provides a system 20; 30; comprising:
one or more processors 110;
a memory 120 configured to store: a fully or partially acausal modular parameterized model of an industrial and/or technical process comprising at least one physical sub-model and at least one neural network sub-model used as a universal function approximator for at least partly modelling the industrial and/or technical process, including one or more model parameters of the fully or partially acausal modular parameterized model;
a simulator configured to, by one or more processors 110, simulate the industrial and/or technical process based on the fully or partially acausal modular parameterized (process) model and a corresponding system of differential equations, and
an evaluator configured to, by the one or more processors 110, apply reverse-mode automatic differentiation with respect to the system of differential equations when simulating the industrial and/or technical process in order to generate an evaluation estimate representing an evaluation of the model of the industrial and/or technical process, and
an adaptation module configured to, by the one or more processors 110, receive the evaluation estimate to update at least one model parameter of the fully or partially acausal modular parameterized model of the industrial and/or technical process based on a gradient-descent or ascent procedure.

Exemplary reference can be made to any of FIG. 11, but also any of FIG. 2 to FIG. 10.

For example, the memory 120 may be configured to store: technical sensor data such as one or more time series parameters originating from one or more data collection systems that has monitored the industrial and/or technical process, and the evaluator may be configured to generate the evaluation estimate at least partly based on the technical sensor data.

In a particular example, the system 20; 30; 100 further comprises, as part of the simulator:
a compiler configured to, by the one or more processors 110, receive the parameterized process model and create the system of differential equations; and
one or more differential equation solvers configured to, by the one or more processors 110, receive the system of differential equations and simulate the industrial and/or technical process through time.

By way of example, the differential equation solver(s) may be configured to, by the one or more processors 110, simulate the dynamics of the state(s) of the industrial and/or technical process over time, and the evaluator may be configured to, by the one or more processors 110, generate an estimate of a gradient related to one or more states derived from the differential equation solver(s) with respect to at least one loss function for output to a model adaptation module.

In this way, the adaptation module (model adaptor) is enabled to update at least one model parameter of the parameterized model of the industrial and/or technical process.

For example, the at least one loss function may represent an error of the simulation in modelling the industrial and/or technical process.

More specifically, the at least one loss function may e.g. represent an error between i) the model-based simulated industrial and/or technical process and ii) a real-world representation of the industrial and/or technical process at least partly based on the technical sensor data from the one or more data collection systems.

As an example, the adaptation module may include an optimizer configured to, by the one or more processors 110: receive one or more model parameters from the memory; receive the evaluation estimate from the evaluator and update one or more model parameters based on a gradient-descent or ascent procedure, and store the updated parameters to memory.

For example, the optimizer may be configured to, by the one or more processors 110, receive a gradient estimate from the evaluator and update one or more model parameters using gradient descent on a loss function that encodes the error of the simulation in modelling the industrial and/or technical process.

In such examples, the memory 120 may also be configured to store: a fully or partially acausal modular parameterized control model for modelling a control process performed by the control system 15 controlling at least part of the industrial and/or technical process, including one or more parameters of the parameterized control model. The fully or partially acausal modular parameterized control model may be defined for interaction with at least part of the fully or partially acausal modular parameterized process model of the industrial and/or technical process as optimized by the updated model parameters. The control process is at least partly modeled by one or more neural networks used as universal function approximator(s). The system may further comprise:
a control simulator configured to, by one or more processors 110, simulate the control process based on the fully or partially acausal modular parameterized control model and a corresponding system of differential equations, and
a control objective module configured to, by the one or more processors 110, evaluate a control objective, defined as a control objective function of the states of the control model, of the control system for controlling the industrial and/or technical process;
a control reverse-mode automatic differentiation estimator configured to, by the one or more processors 110, estimate a gradient of the control objective on the control simulation with respect to one or more control parameters using reverse-mode automatic differentiation with respect to the set of differential equations simulating the control process; and
a control optimizer configured to, by the one or more processors 110, receive the gradient from the control reverse-mode automatic differentiation estimator and one or more control parameters, and update the control parameters based on gradient-descent or ascent and store the improved control parameters to the memory 120.

These modules and/or components may be integrated in the simulator, evaluator and/or adaptor for the process model, or implemented in parallel therewith, e.g. as illustrated in FIG. 4 and FIG. 5, respectively.

By way of example, the system may further comprise the control system 15, which uses the control parameters to control the industrial and/or technical process.

For example, an overall system may further comprise the industrial and/or technical system 10 for performing the industrial and/or technical process, as controlled by the control system 15.

According to a second aspect, there is provided a system 20; 30; 100 configured to evaluate and/or adapt one or more technical models related to an industrial and/or technical process. The system 20; 30; 100 is configured to obtain a fully or partially acausal modular parameterized (process) model of the industrial and/or technical process, including one or more model parameters of the fully or partially acausal modular parameterized model, wherein the fully or partially acausal modular parameterized (process) model is defined such that the industrial and/or technical process is at least partly modeled by one or more neural networks used as universal function approximator(s). The system 20; 30; 100 is also configured to simulate the industrial and/or technical process based on the obtained parameterized process model and a corresponding system of differential equations. Further, the system 20; 30; 100 is configured to apply reverse-mode automatic differentiation with respect to the system of differential equations and generate an estimate representing an evaluation of the process model of the industrial and/or technical process.

The system 20; 30; 100 is further configured to update at least one model parameter of the fully or partially acausal modular parameterized model of the industrial and/or technical process based on the generated evaluation estimate and based on a gradient-descent or ascent procedure, and store the new parameters to memory.

By way of example, the system 20; 30; 100 may be configured to obtain technical sensor data representing one or more states of the industrial and/or technical process at one or more time instances, and the system 20; 30; 100 may be is configured to generate the evaluation estimate at least partly based on the technical sensor data. Further, the system 20; 30; 100 may be configured to simulate the dynamics of the state(s) of the industrial and/or technical process over time, and the system 20; 30; 100 may be configured to generate an estimate of a gradient related to one or more simulated states with respect to at least one loss function representing an error between i) the model-based simulated industrial and/or technical process and ii) a real-world representation of the industrial and/or technical process at least partly based on the technical sensor data.

Optionally, the system 20; 30; 100 may also be configured to obtain a fully or partially acausal modular parameterized control model of a control process performed by a control system (15) controlling at least part of the industrial and/or technical process, including one or more parameters of the fully or partially acausal modular parameterized control model. The fully or partially acausal modular parameterized control model is defined for interaction with at least part of the parameterized model of the industrial and/or technical process as optimized by the updated model parameters. The control process is at least partly modeled by one or more neural networks used as universal function approximator(s). The system 20; 30; 100 is therefore configured to simulate the control process performed by the control system based on the fully or partially acausal modular parameterized control model and a corresponding system of differential equations. The system 20; 30; 100 may then be configured to apply reverse-mode automatic differentiation with respect to the system of differential equations to generate a control model evaluation estimate, and the system 20; 30; 100 may further be configured to update at least one parameter of the fully or partially acausal modular parameterized control model based on the control model evaluation estimate.

Preferably, the system 20; 30; 100 may be configured to transfer at least part of the parameters of the control model to the control system 15 for use as a basis for controlling the industrial and/or technical process.

In particular examples, the system 20; 30; 100 comprises processing circuitry such as one or more processors 110 and memory 120, wherein the memory 120 comprises instructions, which, when executed by the processing circuitry 110, causes the processing circuitry 110 to evaluate and/or adapt one or more technical models related to the industrial and/or technical process.

According to a third aspect, there is provided a control system 15 for a technical and/or industrial system 10, wherein the control system 15 includes and/or interacts with a system 20; 30; 100 according to the above second aspect or its sub-aspects.

According to a fourth aspect, there is provided an industrial and/or technical system 10 comprising a system 20; 30; 100 according to the above second aspect or its sub-aspects and/or a control system 15 according to the third aspect.

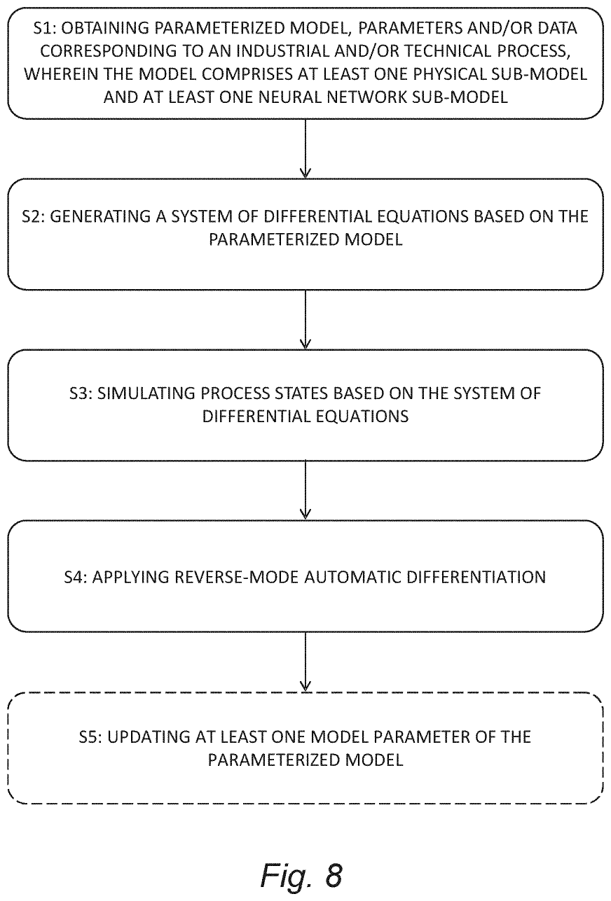

FIG. 8 is a schematic flow diagram illustrating an example of a method, performed by one or more processors, for evaluating and/or adapting one or more technical models related to an industrial and/or technical process according to an embodiment.

Basically, the method comprises:

S1: obtaining a fully or partially acausal modular parameterized model of an industrial and/or technical process comprising at least one physical sub-model and at least one neural network sub-model used as a universal function approximator for at least partly modelling the industrial and/or technical process, including one or more parameters of the fully or partially acausal modular parameterized model;

S2: generating a system of differential equations based on the fully or partially acausal modular parameterized model;

S3: simulating the dynamics of one or more states of the industrial and/or technical process over time based on the system of differential equations; and

S4: applying reverse-mode automatic differentiation with respect to the system of differential equations when simulating the industrial and/or technical process in order to generate an estimate representing an evaluation of the model of the industrial and/or technical process; and

S5: updating at least one model parameter of the fully or partially acausal modular parameterized model of the industrial and/or technical process based on the evaluation estimate using a gradient-descent or ascent procedure.

Preferably, the estimate may be generated at least partly based on technical sensor data originating from the industrial and/or technical process.

By way of example, the step of applying reverse-mode automatic differentiation in order to generate an estimate comprises the step of generating a gradient estimate on a loss function that is based on the simulated states using reverse-mode automatic differentiation.

Optionally, the method may further comprise:
receiving: a fully or partially acausal modular parameterized control model based on at least part of the model of the industrial and/or technical process optimized by the updated model parameter(s) and a parameterized control system for the industrial and/or technical process; a control objective function of the states of the control model encoding an objective of a control of the industrial and/or technical process; and parameters of the control model;
generating states of the control model using one or more differential equation solvers;
generating a gradient estimate on the control objective function with respect to the parameters of the control model using reverse-mode automatic differentiation;
updating one or more of the parameters of the control model using gradient-descent or ascent on the gradient estimate.

By way of example, the updated parameters of the control model may then be stored in memory or the parameterized control system may be configured according to the updated parameters of the control model.

For example, the updated control model parameters may thereby be applied to control the industrial and/or technical process.

For a better understanding, the proposed technology, together with some useful technical terms, will now be described with reference to various non-limiting examples:

A declarative acausal model is a model that describes an industrial process through various equations and that does not specify in every case which variable is the input and which variable is the output. This means that at least some of the equations in the model can be reversed, e.g. that the same efficiency model of pump can be used both to calculate the energy consumption from the water flow and to calculate the water flow from the energy consumption.

Certain variables of the model may also be initiated from sensor data or other data at the solver stage, e.g. using a measured power input to a pump to simulate its flow behaviour given this input. Such data may also be introduced directly in the model at the compiler stage and then be considered part of the model. It is also possible to compile the model and introduce them at the solver stage and/or to compile the solver into a computer readable format and feed parameters to the resulting program.

The division of modelling between the model and the solver for calculating the time dynamics and/or initial values allows components written in these model types to be reused to a much greater extent than traditional object-oriented models at the cost of software and/or hardware complexity.

The model may have some component(s) which is/are based on physical modelling. By way of example, such a component might be simple pressure equations to estimate the temperate based on volume change in a space and with connections to pipes that are defined elsewhere. In another example it could be the acceleration of a turbine by the application of mechanical power. These equations are generally understandable by a human expert, which provides rich possibilities for interpretation and analysis. Many phenomena lack a known simple description, which might make this model type unsuitable in such cases.

The model may have some component(s) designed as one or more neural networks, e.g. used as universal function approximator(s). These are implemented as one or more equations in an acausal modelling language and/or are described in another algorithmic language and/or are provided in computer-readable binary format and/or connected to external software through an interface. Neural network components are typically considered non-interpretable “black box” models that often have a much larger number of parameters than corresponding physical models. They are able to model essentially any possible process given enough data.

Models written in declarative acausal model languages are generally compiled and/or interpreted in several steps. Notably, these commonly includes steps such as model simplification, conversion of data and equations to a format used by a differential equation solver, initialization of variables and the application of the solver to the initial values to create time series.

One possible model component is a modular universal function approximator, such as a neural network. This type of system has gained in popularity due to their ability to imitate any well-behaved non-linear function and be trained with parameterized optimization to reach such a solution in reasonable time complexity. When presented with sensor data there is often a detected difference between the calculated variables and what is detected by the sensors that can be attributed to a difference between the model and the real process being modelled. In such cases it is common practice in many industries to improve the models, when input and output values can be measured, using a simple regression model whose parameters are chosen using the input and output values in mathematical software such as Excel in order to create a regression analysis component in the model. Another common approach is to use genetic optimization or finite difference estimation methods to improve the model parameters. These methods are generally slow and scale poorly into the larger models.

Control systems are generally manually coded, but exceptions exist. A common method to optimize a small-dimensional parameterized control policy is using genetic optimization or finite difference methods, but these have poor computational properties when scaling to larger problems. Yet another common system is to limit the modelling to simple approximate models, such as linear models, in order to be able to apply optimization algorithms suitable for such simple systems, such as the simplex method. This is common in hydropower optimization and other applications.

A careful analysis by the inventor has revealed that the computational challenges faced by the large-scale modelling possible in the new generation of declarative acausal models in combination with universal function approximators can be solved by using techniques known as reverse-mode automatic differentiation, which can be implemented in specially designed differential equation solvers in the overall interpretation/compilation process of the model. These kind of automatic-differentiation reinforced interpretation/compilation systems and/or methods allow scaling properties that are feasible to millions of parameters at the same time. This can be used to calculate derivatives on a control objective function and/or a modelling error function and optimize the model and/or control parameters using a gradient descent/ascent-based method.

According to a particular example, there is thus provided a system that is able to calculate derivative(s), model parameter(s) and/or control parameter(s) in acausal declarative languages using less computational resources than competing methods.

A neural network is one of several well-known machine learning systems/methods that are popular due to an easily parameterized way to increase model complexity and an ability to converge to any of a large class of common functions as this parameter increases. We herein also use neural network to refer to the related support vector machines, which are proven to be largely theoretically equivalent to neural networks.

In general, neural networks, also commonly referred to as artificial neural networks, can be regarded as computing systems vaguely inspired by the biological neural networks that constitute the brain. The neural network itself is not an algorithm, but rather a framework for many different machine learning algorithms to work together and process complex data inputs. In a way, such systems “learn” to perform tasks by considering examples, generally without being programmed with any task-specific rules. A neural network may be based on a collection of connected units or nodes called artificial neurons, which loosely model the neurons in a biological brain. Each connection, like the synapses in a biological brain, can transmit a signal from one artificial neuron to another. An artificial neuron that receives a signal can process it and then signal additional artificial neurons connected to it. In common implementations, the signal at a connection between two artificial neurons can be represented by a real number, and the output of each artificial neuron may be computed by some non-linear function of the sum of its inputs. The connections between artificial neurons are called ‘edges’. Artificial neurons and edges typically have a weight that adjusts as learning proceeds. The weight increases or decreases the strength of the signal at a connection. Artificial neurons may have a threshold such that the signal is only sent if the aggregate signal crosses that threshold. Typically, artificial neurons are aggregated into layers. Different layers may perform different kinds of transformations on their inputs. Signals travel from the first layer (the input layer), to the last layer (the output layer), possibly after traversing the layers multiple times. Many different types of more evolved neural networks have been developed over time, for example convolutional neural networks, recurrent neural networks and hierarchical neural networks.

A declarative acausal model is typically a model written in some declarative acausal modelling language, but may also be stored in an equivalent functionality written in any programming language and/or equivalent computer-readable encoding. Examples of adapted modelling languages notably include Modelica and Modia. These declarative acausal models are necessarily modular in order to be able to reuse components. Declarative acausal models define equations between variables rather than algorithms and generally decide the direction of the calculations at: compile time; by the solver; and/or during execution. In general such languages also support subcomponents with specified directions, i.e. the inclusion of algorithms instead of equations. This means that a causal and/or imperative sub-model, such as an imperative program, can be included within a larger acausal model. Such subcomponents could also be external to the solver in compiled computer-readable form or in a different language with a separate gradient estimation solution. In these cases the required gradient communication can be established to and/or from the subcomponent established through an interface to the solver.

The specific algorithm may be chosen depending on causality chosen by the solver, which allows to model acausal systems where only algorithmic descriptions are available.

An interpreter and/or compiler of the declarative acausal model is typically a system that receives or reads the model from memory. It translates the equations and algorithms there encoded through a series of transformations into a format suitable for direct application in a differential equation solvers. Depending on the context, the differential equation solver is often considered part of the overall modelling language compiler and/or interpreter. This is typically the case if the compiler sends the results to the differential equation solver in order to directly generate a program code or simulation outputs without further human involvement in between. We here use compiler to reference the processes prior to the differential equation solver for clarity, while the overall compilation/interpretation process may also include the solver step.

A differential equation solver, also called a solver or a simulator, receives a series of equations and initial values in an adapted data format and outputs time series describing the state of the modelled system. One example of such solvers is CVODE. The solution of differential equations through time perhaps is the most common use, but we do not limit our invention to such problems. A differential equation solver can also be used to solve a series of equation systems with no time element and/or no time dependency, as well as non-differentiable systems and/or subsystems. One particular example is sub-models that simulate the next time step from the current one without explicitly calculating this, through integrating the rate of change. The differential equation solver relies on a properly balanced system of equations, which if needed can be established after the compilation step if provided data from an external source at this step. This usually relies on compiler knowing which variables that will be defined before the solver such that a proper direction of calculations can be established by the compiler.

As used herein, the expression automatic differentiation typically refers to a family of procedures directly applicable to program code in order to efficiently calculate derivatives without the need for neither human calculation nor automatic symbolic evaluation. An automatic differentiation system typically inputs a program code and outputs a program code that also calculates some derivatives. In stricter terms automatic differentiation refers to series of methods and systems that perform efficient calculation of derivatives and that could, in principle, be applied to any of large set of general program code without much modification. However, automatic differentiation also refers to system and/or methods where the code has been especially adapted for the application of such automatic differentiation methods, e.g. like in deep learning frameworks.

One type of automatic differentiation is reverse-mode differentiation. We here use it to describe both pure reverse-mode differentiation and types of mixed-mode differentiation where some subcomponents of the differentiation process is performed by other computer-implemented differentiation methods, for example forward differentiation and/or symbolic differentiation and/or where the reverse-mode automatic differentiation is included within a larger symbolic differentiation. In reverse mode a graph, tape or similar is used to describe the performed computations during the regular execution and/or compilation, known as the forward step. This graph, tape or similar is then used to perform the computation in approximate reverse order in order to calculate the derivatives of one or more values with respect to one or more parameters. The graph, tape or similar can be: developed dynamically during the processing of the forward step; explicitly pre-calculated at compile time into static graph, tape or similar; and/or used during compilation to create a program code for the reverse-mode.

A reverse-mode automatic differentiation technique can be applied to the differential equation solver to which the compiler feeds its resulting differential equations. The outputs of the differential equations solver can then be derived with respect to any model parameters. The differential equation solver might need some slight modification in order to be differentiable, such as: softening decision boundaries; isolation of stochastic variables through re-parameterization tricks; and/or introduction of noise to cross discrete events, possibly controlled by a temperature or similar parameter that can be adjusted during training.

An error function or loss function typically describes how large our model error is with respect to some data. This is usually defined as a monotonously increasing function, at least in some neighborhood, of the difference between simulated values and measured values. These measured values can in turn be raw sensor inputs or sensor values that have been preprocessed with some function to make the values more relevant and/or accurate. The measured values will make the system of equations overdetermined in some sense, so that we have a calculated value and a measured value that can be compared.

A loss function can be constructed to describe the difference between one or more data from the sensors and one or more corresponding outputs of the differential equation solvers. By using reverse-mode automatic differentiation on the differential equation solver we are able to calculate the gradient of this loss function with respect to one or more parameters with computational efficiency and favourable scalability with the number of parameters in the computation for use in an optimizer.

The loss function can be used as a separate entity that calculates and outputs a signal that corresponds to its gradient or it can be encoded in an appropriate modelling or other computer language format that can be handled by automatic differentiation. Alternatively, it is a variable in the model itself and the loss function is in this case simply an implicit or explicit identification of which state in the model that corresponds to the loss function. There are many other trivial variations on these and similar themes that are obvious to the skilled person.

An optimizer is typically a system that takes a gradient estimate, calculates a gradient step in parameter space and creates new improved parameters according to a gradient descent or ascent strategy. The optimizer commonly has persistent variables between updates, such as a decaying step size and/or momentum. Many well-known such optimizers have convergence guarantees. After one or more steps of the optimizer we will have an improved parameter set that can optionally be stored to a memory. For example, the optimizer may also collect gradient estimates from one or more sources before performing a single gradient update. Parallelization of stochastic simulations in order to estimate the gradient on the underlying distribution is one such example. The parameter updates can be done in the original acausal model or in corresponding variables in any of the intermediate model formats in later stages in the compilation process. The parameter updates between iterations of the optimizer might performed right before the solver in order to minimize overhead from the other compilation processes. In such an operation of the optimizer, the optimizer directly feeds the solver the parameter list and could also use static compilation in the reverse-mode automatic differentiation in order to further minimize computational overheads. However, in other cases this might not be suitable, for example in cases where the parameter values affect the simulation processing steps (i.e. the list of performed processing steps, in contrast to the values used in those steps) and/or where the simulation processing steps are in part stochastic.

Optimizing control systems using sensor data is a complex task and benefits immensely by the reuse of knowledge and ability for humans and artificial intelligence-based components to communicate with each other to describe situations different from the actual system being measured. This can be accomplished by the modular and partly physical simulation described by optimizing modules according to the method and/or system described above. These modules can then be removed and/or rearranged as needed and new physical and/or Artificial Intelligence (AI) modules can be introduced into the model. The new modified model can then describe a new real or hypothetical physical system and reuse the accumulated knowledge therein encoded through this modularity without the need to collect new sensor data specific to the new system. One or more parameters of the desired system that influence its function are designated as control parameters.

A control objective can be regarded as system that is able to take time series or momentary values describing the full or partial state of some industrial process and/or model of an industrial process and automatically estimate the success of the control of the industrial process. The success estimation is usually encoded in a scalar value where higher values are desirable. The design of such control objectives is usually done to comply by business, environmental and physical objectives. We use an appropriately designed such control objective or its output as an input to our system and/or method.

A control optimizer is typically a system that that tries to improve on a parameterized control algorithm. The original optimized module from the optimizer and/or a new module reassembled from modules as above can then be used to create a new control system. Such a problem would traditionally be optimized using genetic optimization and/or reinforcement learning, both of which are computationally challenging in large scale problems. We can instead apply the process described above to compile and solve the differential equations using reverse-mode automatic differentiation in order to produce a gradient estimate in a computationally efficient manner. The automatic differentiation is now used to calculate the gradient of the control objective with respect to our control parameters and direct it to a control optimizer.

The control optimizer receives the gradient estimate from the automatic differentiation applied to the differential equation solver when fed our control model. A suitable gradient-based optimization strategy using the gradient estimate is applied in one or more steps. In case of the common formulation where a high value from the control objective signifies a desirable operation of the industrial process a gradient ascent scheme be applied. After optimization using the control optimizer the control optimizer outputs the final parameters and stores them to memory. The design considerations of the control optimizer are similar to those required when designing an optimizer.

The optimized control parameters can optionally be used in simulation to evaluate the control policy and/or evaluate the industrial and/or technical process using such an optimized control policy. The control parameters can then be implemented in a software and/or hardware implementation of the control and installed in an appropriate industrial and/or technical process. Alternatively, one or more signals created by optimized control policy in the control simulation can be used to directly control the real industrial and/or technical process.

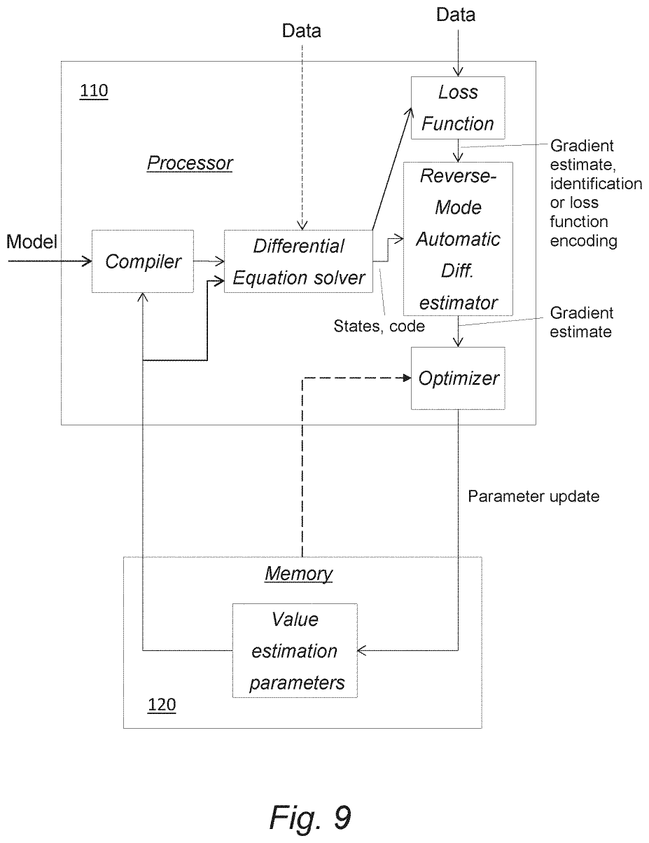

FIG. 9 is a schematic diagram illustrating another particular example of a processor-memory implemented system for model evaluation and/or adaptation related to an industrial and/or technical process. This represents an example of a processor-memory-based implementation, where a compiler, differential equation solver, reverse-mode automatic differentiator estimator and optimizer are executed by a processor 110, and where model parameters are stored and updated in memory 120.

In the following, one or more non-limiting examples of industrial and/or technological applications will be given, including examples of possible input data to the system as well as the operation of the sub-modules.

In a particular example, a Modelica detailed model of a power generator coupled to a turbine is given as an input to the compiler. The generator model is mostly based on physical equations, but includes a neural network model that approximates the effect of temperature and moisture on some internal resistance. The electrical power output over time is considered an unknown in the model that depends on the unknown mechanical power input, or vice versa. The operator has a measurement of the input and output power from sensor data. He uses the compiler to translate the model into Modia and to transform this model to a set of variables and differential equations in the known Julia programming language suitable for input to a Julia-based differential equations solver. This creates a so-called Julia function that is able to simulate the power output given the power input (or-vice versa, if we so instruct the compiler). The operator then applies automatic differentiation to this function in order to create a new function that, when solved, also generates a function that can calculate the derivatives. This new function is our differential equation solver and is compiled into efficient machine code. The operator then feeds the differential equation solver our mechanical power input data in order to generate output data and compare the generated output with the power output collected from the sensor data. This gradient estimate is fed to the reverse-mode automatic differential equation estimator and a gradient estimate is generated for each parameter in the model. This gradient estimate is sent to the optimizer, which reads the parameters and makes a small gradient descent/ascent based update of some of the parameters on the neural network sub-model and some parameters in the general physical generator model with the purpose to reduce the loss. This process is repeated until the loss is reduced sufficiently and the model input-output pairs correspond better to the data collected from sensors.

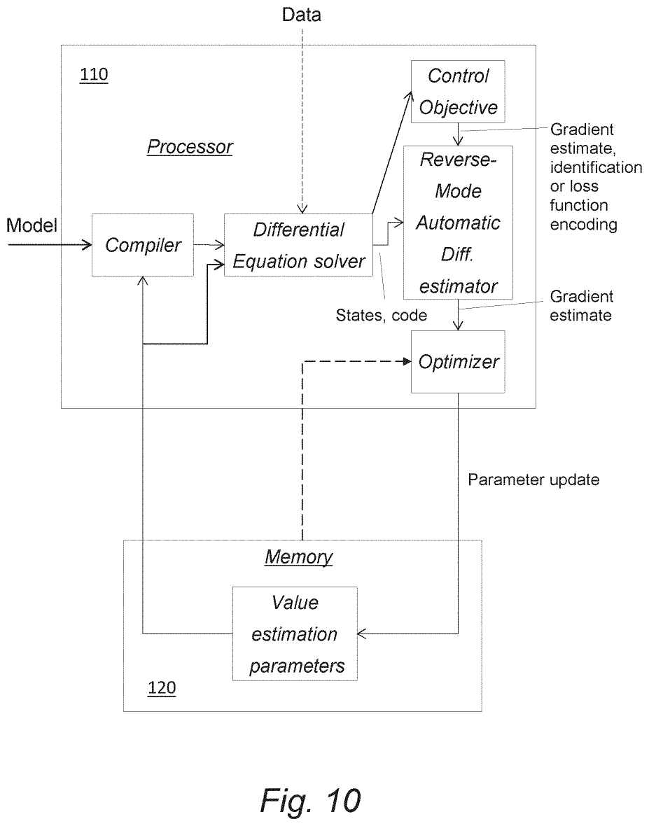

FIG. 10 is a schematic diagram illustrating another particular example of a processor-memory implemented system for model evaluation and/or adaptation related to the control model/system of an industrial and/or technical process. This represents an example of a processor-memory-based implementation, where a compiler, differential equation solver, reverse-mode automatic differentiator estimator and optimizer are executed by a processor 110, and where so-called value estimation parameters are stored and updated in memory 120.

In the following, further non-limiting examples of industrial and/or technological applications will be given, including examples of optional input data to the system as well as the operation of the sub-modules.

In a further example, a local water company designs a Modia model of a municipal wastewater pump and reservoir system and uses a plugin software to geographic information system to create a series of differential equations as a mixture of C++code and precompiled executable binary files that interface with the C++ code through Functional Mock-up Interface (FMI). Some pipe systems in the pump model have been abstracted by the use of trained neural networks. The company defines a control objective that is punishing the model for keeping water levels in the reservoirs at very high levels and punishing it for a value proportional to the electricity costs and includes it as a variable in the Modelica model. The control objective variable is designed such that it sums all past costs and high water levels over simulated time. A physical implementation of a neural network is simulated in the software. The model is compiled into a solver that is implemented in Python with links to C++ code and binary formats and that can be fed hourly electricity prices. The differential equation solver is automatically read by another compiler that generates a corresponding mixture of Python, C++ and executable binary machine-readable code formats that takes the states of the simulation and calculates the gradients of two specified control parameters of interests with respect to the control objective in a so-called static reverse-mode differentiation that generates a partial reverse-mode automatic differentiation estimator. If no electricity price is provided the solver assumes some constant price. The simulated states are fed to the precompiled partial reverse-mode automatic differential estimator and gradients are generated. The optimizer are fed these gradient estimates and uses a gradient descent/ascent strategy to adjust the control parameters. The control parameters are again fed to the differential equation solver, which sends the state to the partial reverse-mode automatic differentiation estimator (with the code being kept static between iterations) in several iterations until a control parameters have approximately reached a local optimum with respect to the control objective. These control parameters are stored to disk and transferred/sold to a customer as the optimal setting for these control parameters in the physical system being modelled by the model.

In another example, a series of hydropower stations and reservoirs can be modelled. In such an example the reservoir volume-height curves and the turbine efficiency curves can be modelled by neural networks, while emergency outlets and piping can be physical in nature. An abundance of data might make a neural network a preferable model, while emergency scenarios happen rarely and might better be modelled using physical a priori knowledge and assumptions than with what little data is available. The parameters of these physical systems can be optimized using the methodology described in here when some additional data is available or they might in the future be replaced entirely with neural network models. The whole model or any part of the model can then be trained using reverse-mode automatic differentiation and available data. Further in our example, once a model of the hydropower stations and reservoirs has been established, we can set up a parameterized control system that takes the reservoir levels and next few days' price of electricity futures as input and outputs the recommended current production level at each power station in order to operate the hydropower stations to maximum efficiency, while at the same time keeping the reservoirs within operating limits thanks to a punishing factor that depends on the extent of the violation of these limits. The model is preferably of a stochastic type in order to create a Monte Carlo type simulation for risk management. This can be trained on historical or simulated external water inflows to the reservoirs, where the simulation can be a statistical distribution that has been developed from a separate dataset. The control system is then trained to set the power production optimally at each instant or over a short period in order to generate the most efficient operation in time, taking non-immediate rewards into consideration in the optimization of the policy. The resulting control system can be simulated repeatedly in the model with different random seeds in order to display approximate confidence intervals to the human operators. The instructions can also be sent directly to a Supervisory Control And Data Acquisition (SCADA) systems in order to directly operate the plants autonomously, which might be especially valuable in smaller hydropower station.

Alternatively in the above example, we can consider a more traditional non-stochastic simulation and set the production level at each instant as an independent parameter. A time series of states is then generated for a few days or weeks and we can optimize the production level at each time step in order to maximize the profit. Several such production plans can be initialized in a grid search and each of them optimized in order to avoid suboptimal local minima.

In another example, a car manufacturer might want to optimize the dynamic fuel injection strategy into an engine. The engine is modelled physically with many unknown parameters. The air pressure-resistance dependency is difficult to model with known physical principles, and a neural network is inserted instead. A stochastic fuel injection strategy is used for exploring the engine parameters in a series of physical tests. The power output and exhaust of the engine can be physically measured, but otherwise the testing engineers lack access to the internals of the engine while in operation. The fuel injection input and power output pairs are used to train the whole model using reverse-mode automatic differentiation to find an optimal physical parameters that would explain what is being measured, including the neural networks. Even though we lack ability to measure the input-output pairs for the neural networks that could be used to train neural network parameters individually, the automatic differentiation process as used according to the invention infers how the whole engine models depends on these parameters and is able to optimize the neural network at the same as the physical parameters. After the model has been optimized to sensor data a series of simple parameterized logical gates controlling the fuel injection is modelled and optimized using reverse-mode automatic differentiation in order to minimize fuel use and minimize certain exhaust gases given a certain power. The logical gates parameters are then used to create a corresponding physical controller of the car engine.

In yet another example, a telecom operator or communication service provider wishes to optimize the operation of its packet-switched communication networks. A contractor develops a hybrid physical model based on a combination of discrete event models modelling individual packets and flow-based models of average transmission rates. The model is implemented in Modelica and sent to the telecom operator. The telecom operator decides to use its databases to optimize the model and adjust its operation based on it. The company adds a neural network to model the communication probabilities and loads as a function of time, weekday and season. The neural network models are refined using real transmission data collected from its operation and reducing the loss using reverse-mode automatic differentiation on the solver of the model in suitable Modia Julia packages.

Further in this example, the telecom operator would wish to evaluate a new expansion of its network capacity. The company adds the corresponding connections in the model, defines a control objective of reducing model loss that is a linear combination of average transfer rates and minimum total packet loss and average latency. The company simulates this over a year of simulated time and applies reverse-mode automatic differentiation to the solver in order to find the derivative of the control objective with respect to various parameters of the transmission control protocol (TCP) and uses the optimizer to perform TCP tuning. The overall performance of such a TCP tuned network is then estimated in the resulting model. The companies compares this modelled performance to the current performance in order to take a decision on whether and/or how to expand the network capacity. If the decision to perform the expansion is taken, the parameters from the TCP tuning can be applied directly to the TCP parameters used in the network.

As can be seen, the proposed technology is generally applicable to any industrial and/or technical system operating in a physical environment with given operational limitations and/or conditions.

For example, the proposed technology may be applied for improved adaptive modeling and/or control of at least part of an industrial and/or technical system for at least one of industrial manufacturing, processing, and packaging, automotive and transportation, mining, pulp, infrastructure, energy and power, telecommunication, information technology, audio/video, life science, oil, gas, water treatment, sanitation and aerospace industry.

It will be appreciated that the methods and devices of described above can be combined and re-arranged in a variety of ways, and that the methods can be performed by one or more suitably programmed or configured digital signal processors and other known electronic circuits (e.g. discrete logic gates interconnected to perform a specialized function, or application-specific integrated circuits).

Many aspects of this invention are described in terms of sequences of actions that can be performed by, for example, elements of a programmable computer system.

The steps, functions, procedures and/or blocks described above may be implemented in hardware using any conventional technology, such as discrete circuit or integrated circuit technology, including both general-purpose electronic circuitry and application-specific circuitry.

Alternatively, at least some of the steps, functions, procedures and/or blocks described above may be implemented in software for execution by a suitable computer or processing device such as a microprocessor, Digital Signal Processor (DSP) and/or any suitable programmable logic device such as a Field Programmable Gate Array (FPGA) device and a Programmable Logic Controller (PLC) device.

It should also be understood that it may be possible to re-use the general processing capabilities of any device in which the invention is implemented. It may also be possible to re-use existing software, e.g. by reprogramming of the existing software or by adding new software components.

It is also possible to provide a solution based on a combination of hardware and software. The actual hardware-software partitioning can be decided by a system designer based on a number of factors including processing speed, cost of implementation and other requirements.

FIG. 11 is a schematic diagram illustrating an example of a computer-implementation 100 according to an embodiment. In this particular example, at least some of the steps, functions, procedures, modules and/or blocks described herein are implemented in a computer program 125; 135, which is loaded into the memory 120 for execution by processing circuitry including one or more processors 110. The processor(s) 110 and memory 120 are interconnected to each other to enable normal software execution. An optional input/output device may also be interconnected to the processor(s) 110 and/or the memory 120 to enable input and/or output of relevant data such as input parameter(s) and/or resulting output parameter(s).

The term ‘processor’ should be interpreted in a general sense as any system or device capable of executing program code or computer program instructions to perform a particular processing, determining or computing task.

The processing circuitry including one or more processors 110 is thus configured to perform, when executing the computer program 125, well-defined processing tasks such as those described herein.

In a particular example, there is provided a computer program 125; 135 comprising instructions, which when executed by at least one processor 110, cause the at least one processor 110 to:
obtain a fully or partially acausal modular parameterized process model of an industrial and/or technical process, and the fully or partially acausal modular parameterized process model is defined such that the industrial and/or technical process is at least partly modeled by one or more neural networks used as universal function approximator(s);
simulate the industrial and/or technical process based on the fully or partially acausal modular parameterized process model and a corresponding system of differential equations;
apply reverse-mode automatic differentiation with respect to the system of differential equations to generate an estimate representing an evaluation of the model of the industrial and/or technical process; and
update at least one parameter of the parameterized process model of the industrial and/or technical process based on the generated evaluation estimate using a gradient-descent or ascent procedure.

In another example, there is provided a computer program 125; 135 comprising instructions, which when executed by at least one processor 110, cause the at least one processor 110 to:
obtain a fully or partially acausal modular parameterized control model of a control process performed by a control system controlling at least part of an industrial and/or technical process, including one or more parameters of the fully or partially acausal modular parameterized control model, wherein the control process is at least partly modeled by one or more neural networks used as universal function approximator(s);
simulate the control process performed by the control system based on the fully or partially acausal modular parameterized control model and a corresponding system of differential equations;
apply reverse-mode automatic differentiation with respect to the system of differential equations to generate a control model evaluation estimate; and
update at least one parameter of the parameterized control model based on the control model evaluation estimate using a gradient-descent or ascent procedure.

The processing circuitry does not have to be dedicated to only execute the above-described steps, functions, procedure and/or blocks, but may also execute other tasks.

Moreover, this invention can additionally be considered to be embodied entirely within any form of computer-readable storage medium having stored therein an appropriate set of instructions for use by or in connection with an instruction-execution system, apparatus, or device, such as a computer-based system, processor-containing system, or other system that can fetch instructions from a medium and execute the instructions.

The software may be realized as a computer program product, which is normally carried on a non-transitory computer-readable medium, for example a CD, DVD, USB memory, hard drive or any other conventional memory device. The software may thus be loaded into the operating memory of a computer or equivalent processing system for execution by a processor. The computer/processor does not have to be dedicated to only execute the above-described steps, functions, procedure and/or blocks, but may also execute other software tasks.

The flow diagram or diagrams presented herein may be regarded as a computer flow diagram or diagrams, when performed by one or more processors. A corresponding apparatus may be defined as a group of function modules, where each step performed by the processor corresponds to a function module. In this case, the function modules are implemented as a computer program running on the processor.

The computer program residing in memory may thus be organized as appropriate function modules configured to perform, when executed by the processor, at least part of the steps and/or tasks described herein.

Alternatively it is possible to realize the module(s) predominantly by hardware modules, or alternatively by hardware, with suitable interconnections between relevant modules. Particular examples include one or more suitably configured digital signal processors and other known electronic circuits, e.g. discrete logic gates interconnected to perform a specialized function, and/or Application Specific Integrated Circuits (ASICs) as previously mentioned. Other examples of usable hardware include input/output (I/O) circuitry and/or circuitry for receiving and/or sending signals. The extent of software versus hardware is purely implementation selection.

It is becoming increasingly popular to provide computing services (hardware and/or software) where the resources are delivered as a service to remote locations over a network. By way of example, this means that functionality, as described herein, can be distributed or re-located to one or more separate physical nodes or servers. The functionality may be re-located or distributed to one or more jointly acting physical and/or virtual machines that can be positioned in separate physical node(s), i.e. in the so-called cloud. This is sometimes also referred to as cloud computing, which is a model for enabling ubiquitous on-demand network access to a pool of configurable computing resources such as networks, servers, storage, applications and general or customized services.

The embodiments described above are to be understood as a few illustrative examples of the present invention. It will be understood by those skilled in the art that various modifications, combinations and changes may be made to the embodiments without departing from the scope of the present invention. In particular, different part solutions in the different embodiments can be combined in other configurations, where technically possible.

1. A system (20; 30; 100) comprising:
one or more processors (110);
a memory (120) configured to store: a fully or partially acausal modular parameterized model of an industrial and/or technical process comprising at least one physical sub-model and at least one neural network sub-model used as a universal function approximator for at least partly modelling the industrial and/or technical process, including one or more model parameters of the fully or partially acausal modular parameterized model;
a simulator configured to, by one or more processors (110), simulate the industrial and/or technical process based on the fully or partially acausal modular parameterized model and a corresponding system of differential equations, and
an evaluator configured to, by the one or more processors (110), apply reverse-mode automatic differentiation with respect to the system of differential equations when simulating the industrial and/or technical process in order to generate an evaluation estimate representing an evaluation of the model of the industrial and/or technical process, and
an adaptation module configured to, by the one or more processors (110), receive the evaluation estimate to update at least one model parameter of the fully or partially acausal modular parameterized model of the industrial and/or technical process based on a gradient-descent or ascent procedure.

2. The system of claim 1, wherein the memory (120) is configured to store:
technical sensor data such as one or more time series parameters originating from one or more data collection systems that has monitored the industrial and/or technical process, and the evaluator is configured to generate the evaluation estimate at least partly based on the technical sensor data.

3. The system of claim 1 or 2, wherein the system (20; 30; 100) further comprises, as part of the simulator:
a compiler configured to, by the one or more processors (110), receive the parameterized process model and create the system of differential equations;
one or more differential equation solvers configured to, by the one or more processors (110), receive the system of differential equations and simulate the industrial and/or technical process through time.

4. The system of claim 3, wherein the differential equation solver(s) is/are configured to, by the one or more processors (110), simulate the dynamics of the state(s) of the industrial and/or technical process over time, and the evaluator is configured to, by the one or more processors (110), generate an estimate of a gradient related to one or more states derived from the differential equation solver(s) with respect to at least one loss function for output to a model adaptation module.

5. The system of claim 4, wherein said at least one loss function represents an error of the simulation in modelling the industrial and/or technical process.

6. The system of claim 5, wherein said at least one loss function represents an error between i) the model-based simulated industrial and/or technical process and ii) a real-world representation of the industrial and/or technical process at least partly based on the technical sensor data from the one or more data collection systems.

7. The system of claim 1, wherein the adaptation module includes:
an optimizer configured to, by the one or more processors (110):
receive one or more model parameters from the memory; receive the evaluation estimate from the evaluator and update one or more model parameters based on a gradient-descent or ascent procedure, and store the updated parameters to memory.

8. The system of claim 7, wherein the optimizer is configured to, by the one or more processors (110), receive a gradient estimate from the evaluator and update one or more model parameters using gradient descent on a loss function that encodes the error of the simulation in modelling the industrial and/or technical process.

9. The system of any of the claims 7 to 8, wherein the memory (120) is also configured to store: a fully or partially acausal modular parameterized control model for modelling a control process performed by a control system (15) controlling at least part of the industrial and/or technical process, including one or more parameters of the parameterized control model, wherein the fully or partially acausal modular parameterized control model is defined for interaction with at least part of the fully or partially acausal modular parameterized model of the industrial and/or technical process as optimized by the updated model parameters, wherein the control process is at least partly modeled by one or more neural networks used as universal function approximator(s);
wherein the system further comprises:
a control simulator configured to, by one or more processors (110), simulate the control process based on the fully or partially acausal modular parameterized control model and a corresponding system of differential equations, and
a control objective module configured to, by the one or more processors (110), evaluate a control objective, defined as a control objective function of the states of the control model, of the control system for controlling the industrial and/or technical process;
a control reverse-mode automatic differentiation estimator configured to, by the one or more processors (110), estimate a gradient of the control objective on the control simulation with respect to one or more control parameters using reverse-mode automatic differentiation with respect to the set of differential equations simulating the control process; and
a control optimizer configured to, by the one or more processors (110), receive the gradient from the control reverse-mode automatic differentiation estimator and one or more control parameters, and update the control parameters based on gradient-descent or ascent and store the improved control parameters to the memory (120).

10. The system of claim 9, further comprising a control system (15) using said control parameters to control the industrial and/or technical process.

11. The system of claim 10, further comprising an industrial and/or technical system (10) for performing the industrial and/or technical process, as controlled by said control system (15).

12. A system (20; 30; 100) configured to evaluate and/or adapt one or more technical models related to an industrial and/or technical process,
wherein the system (20; 30; 100) is configured to obtain a fully or partially acausal modular parameterized model of the industrial and/or technical process, including one or more model parameters of the fully or partially acausal modular parameterized model, wherein the fully or partially acausal modular parameterized model is defined such that the industrial and/or technical process is at least partly modeled by one or more neural networks used as universal function approximator(s);
wherein the system (20; 30; 100) is configured to simulate the industrial and/or technical process based on the fully or partially acausal modular parameterized model and a corresponding system of differential equations, and
wherein the system (20; 30; 100) is configured to apply reverse-mode automatic differentiation with respect to the system of differential equations and generate an estimate representing an evaluation of the process model of the industrial and/or technical process, and
wherein the system (20; 30; 100) is configured to update at least one model parameter of the fully or partially acausal modular parameterized model of the industrial and/or technical process based on the generated evaluation estimate and based on a gradient-descent or ascent procedure, and store the new parameters to memory.

13. The system of claim 12, wherein the system (20; 30; 100) is configured to obtain technical sensor data representing one or more states of the industrial and/or technical process at one or more time instances, and the system (20; 30; 100) is configured to generate the evaluation estimate at least partly based on the technical sensor data,
wherein the system (20; 30; 100) is configured to simulate the dynamics of the state(s) of the industrial and/or technical process over time, and the system (20; 30; 100) is configured to generate an estimate of a gradient related to one or more simulated states with respect to at least one loss function representing an error between i) the model-based simulated industrial and/or technical process and ii) a real-world representation of the industrial and/or technical process at least partly based on the technical sensor data.

14. The system of claim 12 or 13, wherein the system (20; 30; 100) is also configured to obtain a fully or partially acausal modular parameterized control model of a control process performed by a control system (15) controlling at least part of the industrial and/or technical process, including one or more parameters of the fully or partially acausal modular parameterized control model, wherein the fully or partially acausal modular parameterized control model is defined for interaction with at least part of the parameterized model of the industrial and/or technical process as optimized by the updated model parameters, wherein the control process is at least partly modeled by one or more neural networks used as universal function approximator(s);
wherein the system (20; 30; 100) is configured to simulate the control process performed by the control system based on the fully or partially acausal modular parameterized control model and a corresponding system of differential equations;
wherein the system (20; 30; 100) is configured to apply reverse-mode automatic differentiation with respect to the system of differential equations to generate a control model evaluation estimate; and
wherein the system (20; 30; 100) is configured to update at least one parameter of the fully or partially acausal modular parameterized control model based on the control model evaluation estimate.

15. The system of claim 14, wherein the system (20; 30; 100) is configured to transfer at least part of the parameters of the control model to the control system (15) for use as a basis for controlling the industrial and/or technical process.

16. The system of any of the claims 12 to 15, wherein the system (20; 30; 100) comprises processing circuitry (110) and memory (120), wherein the memory (120) comprises instructions, which, when executed by the processing circuitry (110), causes the processing circuitry (110) to evaluate and/or adapt the one or more technical models related to the industrial and/or technical process.

17. A control system (15) for a technical and/or industrial system (10), wherein the control system (15) includes and/or interacts with a system (20; 30; 100) according to any of the claims 12 to 16.

18. An industrial and/or technical system (10) comprising a system (20; 30; 100) according to any of the claims 12 to 16 and/or a control system (15) according to claim 17.

19. A method, performed by one or more processors, for evaluating and/or adapting one or more technical models related to an industrial and/or technical process, said method comprising:
obtaining (S1) a fully or partially acausal modular parameterized model of an industrial and/or technical process comprising at least one physical sub-model and at least one neural network sub-model used as a universal function approximator for at least partly modelling the industrial and/or technical process, including one or more parameters of the fully or partially acausal modular parameterized model;
generating (S2) a system of differential equations based on the fully or partially acausal modular parameterized model;
simulating (S3) the dynamics of one or more states of the industrial and/or technical process over time based on the system of differential equations; and
applying (S4) reverse-mode automatic differentiation with respect to the system of differential equations when simulating the industrial and/or technical process in order to generate an estimate representing an evaluation of the model of the industrial and/or technical process; and
updating (S5) at least one model parameter of the fully or partially acausal modular parameterized model of the industrial and/or technical process based on the evaluation estimate using a gradient-descent or ascent procedure.

20. The method of claim 19, wherein the estimate is generated at least partly based on technical sensor data originating from the industrial and/or technical process.

21. The method of claim 19 or 20, wherein the step of applying reverse-mode automatic differentiation in order to generate an estimate comprises the step of generating a gradient estimate on a loss function that is based on the simulated states using reverse-mode automatic differentiation.

22. The method of claim 19, further comprising:
receiving: a fully or partially acausal modular parameterized control model based on at least part of the model of the industrial and/or technical process optimized by the updated model parameter(s) and a parameterized control system for the industrial and/or technical process; a control objective function of the states of the control model encoding an objective of a control of the industrial and/or technical process; and parameters of the control model;
generating states of the control model using one or more differential equation solvers;
generating a gradient estimate on the control objective function with respect to the parameters of the control model using reverse-mode automatic differentiation;
updating one or more of the parameters of the control model using gradient-descent or ascent on the gradient estimate.

23. The method of claim 22, wherein the updated parameters of the control model are stored in memory or the parameterized control system is configured according to the updated parameters of the control model.

24. The method of any of the claims 19 to 23, wherein the method is applied for adaptive modeling and/or control of at least part of an industrial and/or technical system for at least one of industrial manufacturing, processing, and packaging, automotive and transportation, mining, pulp, infrastructure, energy and power, telecommunication, information technology, audio/video, life science, oil, gas, water treatment, sanitation and aerospace industry.

25. A computer program (125; 135) comprising instructions, which when executed by at least one processor (110), cause the at least one processor (110) to:
obtain a fully or partially acausal modular parameterized model of an industrial and/or technical process, and the fully or partially acausal modular parameterized model is defined such that the industrial and/or technical process is at least partly modeled by one or more neural networks used as universal function approximator(s);
simulate the industrial and/or technical process based on the fully or partially acausal modular parameterized model and a corresponding system of differential equations;
apply reverse-mode automatic differentiation with respect to the system of differential equations to generate an estimate representing an evaluation of the model of the industrial and/or technical process; and
update at least one parameter of the parameterized process model of the industrial and/or technical process based on the generated evaluation estimate using a gradient-descent or ascent procedure.

26. A computer program (125; 135) comprising instructions, which when executed by at least one processor (110), cause the at least one processor (110) to:
obtain a fully or partially acausal modular parameterized control model of a control process performed by a control system controlling at least part of an industrial and/or technical process, including one or more parameters of the fully or partially acausal modular parameterized control model, wherein the control process is at least partly modeled by one or more neural networks used as universal function approximator(s);
simulate the control process performed by the control system based on the fully or partially acausal modular parameterized control model and a corresponding system of differential equations;
apply reverse-mode automatic differentiation with respect to the system of differential equations to generate a control model evaluation estimate; and
update at least one parameter of the parameterized control model based on the control model evaluation estimate using a gradient-descent or ascent procedure.

27. A computer-program product comprising a non-transitory computer-readable medium (120; 130) having stored thereon a computer program (125; 135) of claim 25 or 26.
